(19) United States
(12) Patent Application Publication
(10) Pub. No.: US 2025/0246489 A1
(43) Pub. Date: Jul. 31, 2025

(54) PACKAGE STRUCTURE

(71) Applicant: Advanced Semiconductor Engineering, Inc., Kaohsiung (TW)

(72) Inventors: Wei Tsung CHEN, Kaohsiung (TW); Chun-Hsiung CHEN, Kaohsiung (TW)

(73) Assignee: Advanced Semiconductor Engineering, Inc., Kaohsiung (TW)

(21) Appl. No.: 18/424,686

(22) Filed: Jan. 26, 2024

(51) Int. Cl. H01L 23/13; H01L 23/00; H01L 23/498; H01L 23/552

(52) U.S. Cl. CPC H01L 23/13; H01L 23/49827; H01L 24/48; H01L 23/552; H01L 24/06; H01L 24/29; H01L 24/32; H01L 24/33; H01L 24/73; H01L 2224/06181; H01L 2224/2919; H01L 2224/29191; H01L 2224/32145; H01L 2224/32237; H01L 2224/3224; H01L 2224/33181; H01L 2224/48091; H01L 2224/48145; H01L 2224/48227; H01L 2224/4824; H01L 2224/73215; H01L 2224/73265; H01L 2924/066; H01L 2924/0665; H01L 2924/07025; H01L 2924/0715

(57) ABSTRACT

A package structure is provided. The package structure includes a substrate, an electronic component, and a stop layer. The substrate has a through hole including a stepped sidewall structure including a tread. The electronic component is disposed supported by the tread of the stepped sidewall structure. The stop layer is disposed on the top surface of the tread.

### BACKGROUND

### 1. Technical Field

The present disclosure relates generally to a package structure.

### 2. Description of the Related Art

Currently, for manufacturing a package structure including a chip or component with input/output (I/O) terminals on opposite sides, a ceramic substrate may be manufactured to provide a specific structure for the chip or component to be disposed therein, such that the I/O terminals on opposite sides of the chip or component can be exposed by the ceramic substrate for electrical connection. However, the cost and the difficulty for manufacturing the ceramic substrate with the specific structure may be relatively high, and the brittle texture of the ceramic substrate may render the ceramic substrate relatively fragile and thus reducing the yield.

### SUMMARY

In one or more arrangements, a package structure includes a substrate, an electronic component, and a stop layer. The substrate has a through hole including a stepped sidewall structure. The electronic component is supported by the tread of the stepped sidewall structure. The stop layer is disposed on the top surface of the tread.

In one or more arrangements, a package structure includes a substrate, an electronic component, and a first conductive element. The substrate has a through hole extending between a top surface and a bottom surface of the substrate. The electronic component is disposed over the through hole of the substrate, wherein the electronic component has a lower surface adjacent to the top surface of the substrate, and an upper surface distal from the top surface of the substrate, and the electronic component includes a first pad adjacent to the upper surface of the electronic component. The first conductive element passes the through hole to connect the first pad to the bottom surface of the substrate.

In one or more arrangements, a package structure includes a substrate and an electronic component. In a cross-sectional view perspective, the substrate has a through hole. In a cross-sectional view perspective, the electronic component is disposed over the through hole and has a first side surface and a second side surface opposite to the first side surface, the first side surface vertically overlaps the substrate, and the second side surface does not vertically overlap the substrate.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a cross-section of a package structure in accordance with some arrangements of the present disclosure.

FIG. 1C is a top view of a package structure in accordance with some arrangements of the present disclosure.

FIG. 2 is a top view of a package structure in accordance with some arrangements of the present disclosure.

FIG. 3A is a perspective view of a package structure in accordance with some arrangements of the present disclosure.

FIG. 3B is a perspective view of a package structure in accordance with some arrangements of the present disclosure.

FIG. 4A is a cross-section of a package structure in accordance with some arrangements of the present disclosure.

FIG. 4B is a cross-section of a package structure in accordance with some arrangements of the present disclosure.

FIG. 4C is a cross-section of a package structure in accordance with some arrangements of the present disclosure.

FIG. 4D is a cross-section of a package structure in accordance with some arrangements of the present disclosure.

FIG. 4E is a cross-section of a package structure in accordance with some arrangements of the present disclosure.

FIG. 4F is a top view of a package structure in accordance with some arrangements of the present disclosure.

FIG. 5A, FIG. 5B, FIG. 6A, FIG. 6B, FIG. 7A, FIG. 7B, FIG. 7C, FIG. 8A, FIG. 8B, FIG. 8C, FIG. 9A, FIG. 9B, FIG. 10A, FIG. 10B, FIG. 11, FIG. 12, and FIG. 13 illustrate various stages of an exemplary method for manufacturing a package structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

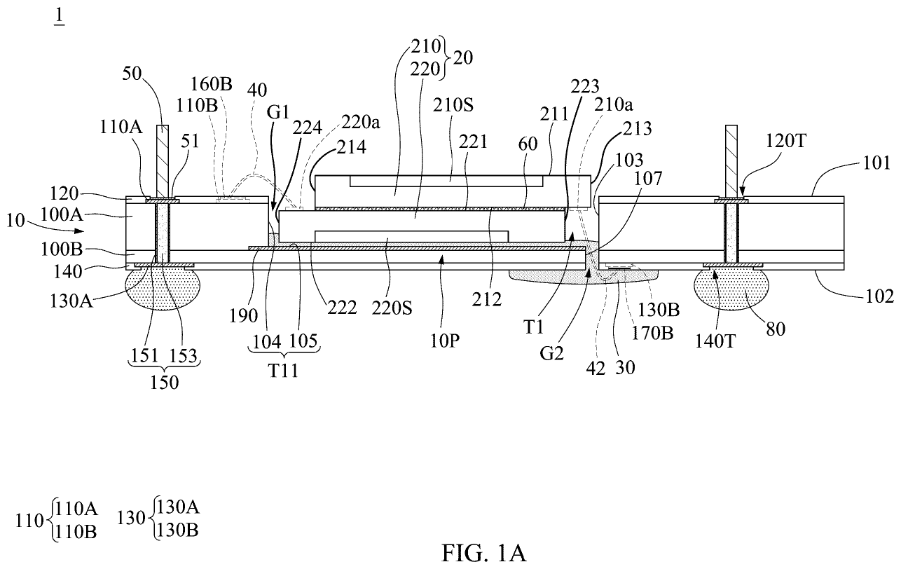

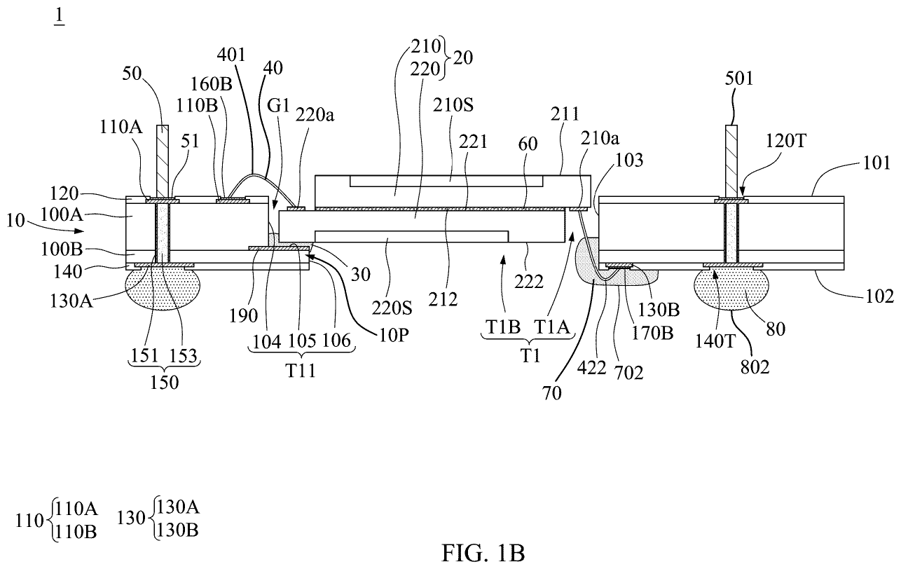

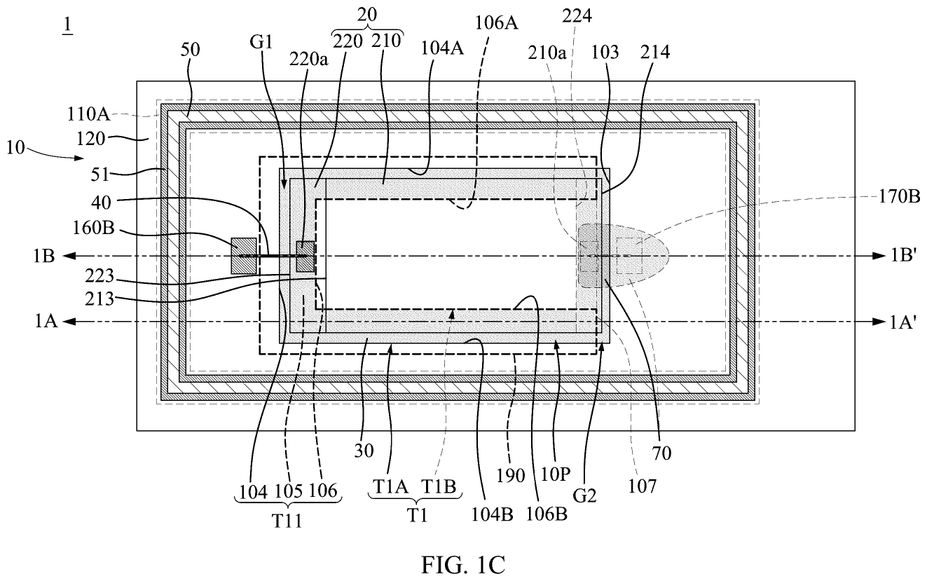

FIG. 1A is a cross-section of a package structure 1 in accordance with some arrangements of the present disclosure. FIG. 1B is a cross-section of a package structure 1 in accordance with some arrangements of the present disclosure. FIG. 1C is a top view of a package structure 1 in accordance with some arrangements of the present disclosure. In some arrangements, FIG. 1A shows a cross-section along a line 1A-1A′ in FIG. 1C, and FIG. 1B shows a cross-section along a line 1B-1B′ in FIG. 1C. The package structure 1 may include a substrate 10, an electronic component 20, an adhesive layer 30, conductive wires 40 and 42, a spacer structure 50, an adhesive element 51, a protective element 70, and electrical contacts 80. Please be noted that some elements (e.g., the conductive wires 40 and 42, pads 210a and 220a, portions 110B and 130B, and protective films 160B and 170B) are illustrated in dash lines to indicate the relative positions from a side view perspective.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, which may include a plurality of conductive traces and/or conductive vias. The interconnection structure may include a redistribution layer (RDL) and/or a grounding element. In some arrangements, the substrate 10 may include an organic substrate or a leadframe. In some arrangements, the substrate 10 may include a ceramic material or a metal plate. In some arrangements, the substrate 10 may include a two-layer substrate which includes a core layer and a conductive material and/or structure disposed on an upper surface and a bottom surface of the substrate. The substrate 10 may include a semiconductor wafer or an electronic component. The electronic component may be a chip or a die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the substrate 10 may include one or more conductive elements, surfaces, contacts, or pads.

In some arrangements, the substrate 10 has a surface 101 (also referred to as “a top surface” or “an upper surface”) and a surface 102 (also referred to as “a bottom surface” or “a lower surface”) opposite to the surface 101. In some arrangements, referring to FIGS. 1A to 1C, the substrate 10 further has a plurality of lateral surfaces (e.g., surfaces 103, 104, 104A, 104B, 106, 106A, 106B, and 107). In some arrangements, the substrate 10 further has an intermediate surface (e.g., a surface 105). In some arrangements, the substrate 10 defines a through hole T1. In some arrangements, the through hole T1 extends between the surface 101 (or the top surface) and the surface 102 (or the bottom surface) of the substrate 10. In some arrangements, the through hole T1 includes at least a straight vertical sidewall or a substantially vertical inner sidewall (e.g., the surface 103) defining the through hole T1 and a stepped sidewall structure T11 in a cross-sectional view perspective. The substantially vertical inner sidewall (e.g., the surface 103) has a substantially flat surface extending continuously from the surface 101 to the surface 102 of the substrate 10 in a cross-sectional view perspective.

In some arrangements, the substrate 10 includes base layers 100A and 100B, circuit layers 110 and 130, dielectric layers 120 and 140, and one or more conductive vias 150. In some arrangements, the base layers 100A and 100B may independently be or include a semiconductor substrate or other suitable materials or elements included in the substrate 10 as described above. In some arrangements, the base layers 100A and 100B may independently include a dielectric material, e.g., polyimide (PI). In some arrangements, the circuit layer 110 is adjacent to the surface 101 (or the top surface), and the circuit layer 130 is adjacent to the surface 102 (or the bottom surface). In some arrangements, the circuit layer 110 may be or include conductive pads, conductive layers, conductive patterns, conductive portions, or the like. In some arrangements, the circuit layer 110 includes portions 110A and 110B. The portions 110A and 110B may be electrically disconnected from one another. In some arrangements, the circuit layer 110 further includes a protective film 160B on the portion 110B. The protective film may be or include a metal finish layer, such as NiAu alloy or other suitable materials. In some arrangements, the circuit layer 130 may be or include conductive pads, conductive layers, conductive patterns, conductive portions, or the like. In some arrangements, the circuit layer 130 includes portions 130A and 130B. The portions 130A and 130B may be electrically disconnected from one another. In some arrangements, the circuit layer 130 further includes a protective film 170B on the portion 130B. The protective film may be or include a metal finish layer, such as NiAu alloy or other suitable materials. In some arrangements, the package structure 1 further includes a metal layer 190 disposed between the electronic component 20 and the stepped sidewall structure T11. In some arrangements, the metal layer 190 is partially embedded in the base layers 100A and 100B. In some arrangements, the metal layer 190 includes a portion exposed to the through hole T1 and another portion not exposed to the through hole T1. In some arrangements, a portion of the metal layer 190 is disposed between the base layer 100A and the base layer 100B. The metal layer 190 may serve as a stop layer or a laser stopper for blocking laser from penetrating through the metal layer 190. The metal layer 190 may include a metal material, e.g., copper (Cu).

In some arrangements, the dielectric layers 120 and 140 are disposed on the circuit layers 110 and 130, respectively. The dielectric layer 120 and the dielectric layer 140 may collectively construct or be referred to as an insulating structure. In some arrangements, the dielectric layer 120 has one or more openings 120T exposing portions of the circuit layer 110. In some arrangements, the protective film 160B is exposed by the opening 120T. In some arrangements, the dielectric layer 140 has one or more openings 140T exposing portions of the circuit layer 130. In some arrangements, the protective film 170B is exposed by the opening 140T. In some arrangements, the conductive via 150 electrically connects the surface 101 to the surface 102 of the substrate 10. In some arrangements, the conductive vias 150 penetrate the base layers 100A and 100B. In some arrangements, the conductive via 150 includes a conductive liner 151 and an insulative filling layer 153 (e.g., a dielectric layer). In some arrangements, one of the conductive vias 150 is electrically connected to the portion 110A of the circuit layer 110 and the portion 130A of the circuit layer 130.

In some arrangements, through hole T1 of the substrate 10 is defined by a straight vertical sidewall (e.g., the surface 103) and a stepped sidewall structure T11. In some arrangements, the straight vertical sidewall includes a substantially flat surface (e.g., the surface 103) extending continuously from a top surface (e.g., the surface 101) to a bottom surface (e.g., the surface 102) of the substrate 10.

In some arrangements, the substrate 10 has through holes T1A and a through hole T1B connected to the through hole T1A. In some arrangements, the through hole T1 includes the through holes T1A and T1B. The through hole T1A may be over and connected to the through hole TIB. Referring to FIGS. 1A to 1C, the through hole TIA may be defined or surrounded by a plurality of lateral sidewalls (e.g., surfaces 104, 104A, 103, and 104B), and the through hole T1B may be defined or surrounded by a plurality of lateral sidewalls (e.g., surfaces 106, 106A, 103, and 106B). In some arrangements, the through hole T1A and the through hole T1B share a same vertical sidewall (e.g., the surface 103) of the substrate 10.

Referring to FIGS. 1A to 1C, in some arrangements, a width (e.g., a distance between the surface 104 and the surface 103) of the through hole T1A is greater than a width (e.g., a distance between the surface 106 and the surface 103) of the through hole T1B. In some arrangements, the substrate 10 includes a platform 10P protruded from a sidewall (e.g., the surface 104) of the through hole T1. The platform 10P may be referred to as a tread. In some arrangements, the stop layer or the laser stop layer (e.g., the metal layer 190) is disposed on a top surface of the tread (or the platform 10P). In some arrangements, the platform 100P is protruded from three sidewalls (e.g., the surfaces 104, 104A, and 104B) of the through hole T1. In some arrangements, the through hole TIA and the through hole TIB collectively define a platform 10P. In some arrangements, the width of the through hole T1A is greater than the width of the through hole T1B by a width of the platform 10P. In some arrangements, a vertical projection of the through hole T1B is within the through hole T1A. In some arrangements, a pad (e.g., the portion 130A) of the substrate 10 is outside of the through hole T1A and the through hole T1B. In some arrangements, a sidewall (e.g., the surface 104) of the through hole T1A has a first portion adjacent to the platform 10P and a second portion distal from the platform 10P, and a roughness of the first portion is less than a roughness of the second portion.

In some arrangements, the metal layer 190 defines a step surface (e.g., the surface 105) of the stepped sidewall structure T11 for supporting the electronic component 20. In some arrangements, the metal layer 190 includes a portion exposed by the base layer 100A. In some arrangements, an edge (e.g., the surface 106 and/or the surface 107) of the stepped sidewall structure T11 is substantially aligned with an edge of the metal layer 190. In some arrangements, a sidewall (e.g., the surface 104) defining the through hole T1 has a first portion adjacent to the metal layer 190 (or the stop layer) and a second portion distal from the metal layer 190, and a roughness of the first portion is less than a roughness of the second portion. In some arrangements, the first portion is formed by a mechanical drilling operation for forming the through hole T1, the second portion is formed by a laser drilling operation for forming the through hole T1, and the metal layer 190 serves as a stop layer for the laser drilling operation.

In some arrangements, the stepped sidewall structure T11 has an edge (e.g., the surface 107) facing and spaced apart from the straight vertical sidewall (e.g., the surface 103) by a gap G2. In some arrangements, the stepped sidewall structure T11 further has a lateral surface (e.g., the surface 104) facing and spaced apart from the electronic component 20 by a gap G1. In some arrangements, the gap G1 is smaller than the gap G2. In some arrangements, the stepped sidewall structure T11 may include or defined by the surfaces 104, 105, and 106.

In some arrangements, the electronic component 20 is disposed at a side of the substrate 10. For example, the electronic component 20 is at a side of the base layer 100B of the substrate 10. In some arrangements, the electronic component 20 may be disposed in the through hole T1 of the substrate 10. In some arrangements, the electronic component 20 is partially disposed within the through hole T1 and partially protruded beyond the surface 101 of the substrate 10. In some arrangements, the electronic component 20 has a surface 211 (also referred to as “a top surface” or “an upper surface”), a surface 221 (also referred to as “a top surface” or “an upper surface”), a surface 212 (also referred to as “a bottom surface” or “a lower surface”) opposite to the surface 211, a surface 222 (also referred to as “a bottom surface” or “a lower surface”) opposite to the surface 211 or the surface 221, and at least surfaces 213, 214, 223, and 244 (also referred to as “lateral side surfaces”). In some arrangements, the top surface (e.g., the surface 211) and the bottom surface (e.g., the surface 222) of the electronic component 20 are exposed by the through hole T1. In some arrangements, the surface 211 of the electronic component 20 is protruded beyond the surface 101 (or the top surface) of the substrate 10. In some arrangements, the surface 211 of the electronic component 20 and the surface 101 of the substrate 10 are at different elevations. In some arrangements, the lateral side surface (e.g., the surfaces 213, 214, 223, and 244) of the electronic component 20 is separated from or spaced apart from the sidewall of the through hole T1. In some arrangements, a thickness of the electronic component 20 is greater than a thickness of the substrate 10. In some arrangements, a thickness of the electronic component 20 is greater than a depth of the through hole T1. The electronic component 20 may be or include a sensor. The sensor may be or include a micro-electromechanical system (MEMS) sensor, a temperature sensor, a pressure sensor, a humidity sensor, an inertial force sensor, a chemical species sensor, a magnetic field sensor, or a combination thereof.

In some arrangements, the electronic component 20 is disposed on or supported by the tread (e.g., the platform 10P) of the stepped sidewall structure T11 in the through hole T1. In some arrangements, the electronic component 20 is disposed on the platform 10P in the through hole T1. In some arrangements, the electronic component 20 has a first active surface (e.g., the surface 211) and a second active surface (e.g., the surface 222) opposite to the first active surface, and the first active surface (or the surface 211) and the second active surface (or the surface 222) are exposed by the through hole T1A and the through hole T1B, respectively. In some arrangements, the first active surface (or the surface 211) is protruded beyond the through hole T1. In some arrangements, the electronic component 20 is disposed in the through hole T1A without extending into the through hole T1B. In some arrangements, the electronic component 20 includes pads 210a and 220a (also referred to as “conductive pads” or “conductive terminals”) that are within the through hole T1 and wire-bonded to the substrate 10. In some arrangements, the pad 210a and the pad 220a face opposite directions. In some arrangements, the electronic component 20 includes a device 210 (also referred to as “a chip” or “an electronic device”), a device 220 (also referred to as “a chip” or “an electronic device”) stacked with first device 210, and a connection element 60 between and connecting the device 210 and the device 220. In some arrangements, the pad 210a is disposed on a portion of the device 210 exposed by the device 220. In some arrangements, the pad 220a is disposed on a portion of the device 220 exposed by the device 210. In some arrangements, the connection element 60 includes an insulating adhesive layer (e.g., a die attach film (DAF)) or a conductive film (e.g., an anisotropic conductive film (ACF)).

In some arrangements, the device 210 includes a sensing element 210S adjacent to the surface 211. In some arrangements, the sensing element 210S is exposed by the surface 211 of the device 210. In some arrangements, the sensing element 210S is exposed by the through hole T1A of the substrate 10. In some arrangements, the device 210 includes an active surface (e.g., the surface 211) and a backside surface (e.g., the surface 212) connected to the connection element 60. In some arrangements, the pad 210a of the device 210 is wire-bonded to the substrate 10. The device 210 may includes an interconnection element (e.g., a conductive via) that connects the sensing element 210S to the pad 210a.

In some arrangements, the device 220 includes a sensing element 220S adjacent to the surface 222. In some arrangements, the sensing element 220S is exposed by the surface 222 of the device 220. In some arrangements, the sensing element 220S is exposed by the through hole T1B of the substrate 10. In some arrangements, the device 220 includes an active surface (e.g., the surface 222) and a backside surface (e.g., the surface 221) connected to the connection element 60. In some arrangements, the pad 220a of the device 220 is wire-bonded to the substrate 10. The device 220 may includes an interconnection element (e.g., a conductive via) that connects the sensing element 220S to the pad 220a.

The adhesive layer 30 may be disposed between the electronic component 20 and the substrate 10. In some arrangements, the adhesive layer 30 connects the electronic component 20 to the stepped sidewall structure T11. In some arrangements, the adhesive layer 30 connects or adheres the electronic component 20 to the platform 10P. In some arrangements, the adhesive layer 30 is partially within the through hole T1A and partially within the through hole T1B. In some arrangements, the adhesive layer 30 contacts a sidewall (e.g., the surface 104) of the through hole T1A and a sidewall (e.g., the surface 106) of the through hole T1B. In some arrangements, the adhesive layer 30 is further disposed in the gap G1. In some arrangements, the adhesive layer 30 is further filled in the gap G2. In some arrangements, the adhesive layer 30 further contacts a portion of the edge (e.g., the surfaces 106 and 107) of the stepped sidewall structure T11. In some arrangements, the adhesive layer 30 further contacts the straight vertical sidewall (e.g., the surface 103) of the through hole T1. In some arrangements, the pads 210a and 220a are exposed by the adhesive layer 30. In some arrangements, the metal layer 190 includes a portion exposed by the substrate 10, and the adhesive layer 30 is disposed on the exposed portion of the metal layer 190. In some arrangements, the metal layer 190 includes a portion exposed by the base layer 100A and contacting the adhesive layer 30. In some arrangements, the adhesive layer 30 may be or include an underfill or an encapsulant. The adhesive layer 30 may include an epoxy resin, a molding compound (e.g., an epoxy molding compound or other molding compound), polyimide, a phenolic compound or material, a material including a silicone dispersed therein, or a combination thereof.

The conductive wire 40 may connect the electronic component 20 to the substrate 10. In some arrangements, the device 220 is electrically connected to the substrate 10 through the conductive wire 40. In some arrangements, the conductive wire 40 protruded beyond the surface 101 of the substrate 10 is exposed by the adhesive layer 30. In some arrangements, the conductive wire 40 electrically connects the pad 220a of the device 220 to the surface 101 of the substrate 10. In some arrangements, the conductive wire 40 electrically connects the pad 220a of the device 220 to the protective film 160B and the portion 110B of the circuit layer 110 of the substrate 10. The conductive wire 40 may be referred to as a conductive element.

The conductive wire 42 may connect the electronic component 20 to the substrate 10. In some arrangements, the device 210 is electrically connected to the substrate 10 through the conductive wire 42. In some arrangements, the conductive wire 42 is spaced apart from the adhesive layer 30. In some arrangements, the conductive wire 42 connects or electrically connects the pad 210a of the device 210 to the surface 102 (or the bottom surface) of the substrate 10. In some arrangements, the conductive wire 42 electrically connects the pad 210a of the device 210 to the protective film 170B and the portion 130B of the circuit layer 130 of the substrate 10. In some arrangements, a portion of the adhesive layer 30 horizontally overlaps a portion of the conductive wire 42. In some arrangements, the conductive wire 42 connects the active surface (e.g., the surface 222) of the electronic component 20 to a pad (e.g., the portion 130A) of the substrate 10. In some arrangements, the conductive wire 42 is partially within the through hole T1B. The conductive wire 42 may be referred to as a conductive element.

The spacer structure 50 may be disposed around the conductive wire 40. In some arrangements, an elevation of a top surface 501 of the spacer structure 50 is higher than an elevation of a top end 401 of the conductive wire 40 with respect to the surface 101 of the substrate 10. In some arrangements, the spacer structure 50 is disposed on the surface 101 of the substrate 10 and configured to protect the electronic component 20 from being damaged. In some arrangements, the spacer structure 50 is disposed on the surface 101 of the substrate 10 and defines a space for accommodating the conductive wire 40 and a portion of the electronic component 20 protruded beyond the surface 101 of the substrate 10. In some arrangements, the spacer structure 50 is connected to (or electrically connected to) ground through the conductive via 150. The spacer structure 50 may serve as a shielding element configured to reduce electromagnetic interference (EMI). In some arrangements, the spacer structure 50 may be referred to as or include a spacer, a metal spacer, an interposer, or the like. The spacer structure 50 may be or include a metal frame, a metal wall structure, or a metal lid. In some embodiments, the spacer structure 50 is made of or include a conductive material including, for example, aluminum (Al), copper (Cu), chromium (Cr), tin (Sn), gold (Au), silver (Ag), nickel (Ni) or stainless steel, or a mixture, an alloy, or other combination thereof.

The adhesive element 51 may connect the spacer structure 50 to the substrate 10. In some arrangements, the adhesive element 51 is at least partially within the opening 120T of the dielectric layer 120. In some arrangements, the adhesive element 51 is formed of or includes a conductive material. The adhesive element 51 may be or include a conductive layer (e.g., a metal layer), a conductive adhesive (e.g., a silver paste or a silver gel), or a combination thereof. The adhesive element 51 may be or include a solder material. In some arrangements, the adhesive element 51 electrically connects the spacer structure 50 to the portion 110A of the circuit layer 110.

The protective element 70 may encapsulate a portion of the conductive wire 42. In some arrangements, the protective element 70 encapsulates a bottom end 422 of the conductive wire 42. In some arrangements, the protective element 70 further covers at least a portion of the protective film 170B. As shown in FIG. 1C, in some arrangements, the protective element 70 contacts the adhesive layer 30. In some arrangements, the protective element 70 has a non-uniform thickness along a direction substantially parallel to the surface 1001 of the substrate 10. In some arrangements, the protective element 70 is protruded beyond the bottom surface (e.g., the surface 1002) of the substrate 10. The protective element 70 may include an encapsulant. The encapsulant may include an epoxy resin having fillers, a molding compound (e.g., an epoxy molding compound or other molding compound), polyimide, a phenolic compound or material, a material with a silicone dispersed therein, or a combination thereof. In some arrangements, the protective element 70 may be or include a sealing gel. In some arrangements, the protective element 70 may be or include a sealant.

The electrical contacts 80 may be disposed on the surface 102 of the substrate 10. In some arrangements, an elevation of a bottom surface 802 of the electrical contacts 80 is lower than an elevation of a bottom surface 702 of the protective element 70 with respect to the surface 102 of the substrate 10. In some arrangements, the elevation of a bottom surface 802 of the electrical contacts 80 is lower than an elevation of the bottom end 422 of the conductive wire 42 with respect to the surface 102 of the substrate 10. In some arrangements, the electrical contacts 80 are electrically connected to the circuit layer 130 of the substrate 10. In some embodiments, the electrical contacts 80 include controlled collapse chip connection (C4) bumps, a ball grid array (BGA), or a land grid array (LGA).

The conductive layers, pads, pillars, portions, vias, liners, and/or terminals may independently include a conductive material such as a metal or metal alloy. Examples include Au, Ag, Al, Cu, or an alloy thereof. The dielectric layers may independently include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like.

In some cases where a ceramic substrate is manufactured to provide a specific structure for an electronic component to be disposed therein, such that the I/O terminals on opposite sides of the electronic component can be exposed by the ceramic substrate for electrical connection. However, the cost and the difficulty for manufacturing the ceramic substrate with the specific structure may be relatively high, and the brittle texture of the ceramic substrate may render the ceramic substrate relatively fragile and thus reducing the yield. To solve the above problems, a plastic substrate including a specific structure for the electronic component to be disposed therein may be provided. The plastic substrate may be formed by the following steps: a top cavity and a bottom cavity may be formed from the top surface and the bottom surface of the plastic substrate, respectively, to connect the top cavity and the bottom cavity to form a through hole with a platform defined by the cavities in the plastic substrate, such that the electronic component may be disposed on the platform in the through hole of the plastic substrate. However, it is relatively difficult to precisely control the depths of the top cavity and the bottom cavity during the two-step cavity-forming process from opposite directions, and thus the variations in depths of the cavities may render the as-formed platform to have a non-uniform elevation, which may reduce the yield as well.

According to some arrangements of the present disclosure, the substrate includes two through holes sharing a same straight vertical sidewall that are not formed by drilling from opposite surfaces of the substrate, and the electronic component is disposed on the platform defined by the two through holes. The process for forming the through holes is relatively easy and simplified (e.g., by drilling operations from a same surface of the substrate), the issue of difficulty in controlling the depths of multiple cavities from opposite surfaces can be omitted, thus the yield can be increased, and the cost can be reduced. In addition, both sides or surfaces of the electronic component can be exposed by opposite openings of the through holes, such that both sides or surfaces of the electronic component can be electrically connected to conductive elements (e.g., conductive wires).

Furthermore, according to some arrangements of the present disclosure, the electronic component is adhered to the platform and the sidewall of the through hole by an adhesive layer. The material of the adhesive layer may flow into the relatively narrow gap (e.g., the gap G1) between the electronic component and the sidewall of the through hole and then be cured to form the adhesive layer during the manufacturing process, and thus the gap can be relatively small, such that the overall size of the package structure can be reduced. Moreover, the material of the adhesive layer may overflow to fill the gap (e.g., the gap G2) between the edge of the platform and the sidewall, such that the adhesion between the electronic component and the substrate can be increased without increasing the package size, which is further advantageous to increasing the reliability of the package structure and the yield.

In addition, according to some arrangements of the present disclosure, with the design of the gap (e.g., the gap G2) between the edge of the platform and the sidewall, such that a tolerance in space is further provided when disposing the electronic component in the through hole. Therefore, the electronic component can be prevented from accidentally hitting the sidewall (e.g., the surface 103) of the through hole when being disposed in the through hole. Therefore, the yield can be improved.

Moreover, according to some arrangements of the present disclosure, the spacer structure is taller than the electronic component and the conductive wire over the top surface of the substrate, such that the spacer structure can protect the electronic component and the conductive wire from being damaged. In addition, the spacer structure may be further electrically connected to ground, such that the spacer structure can further serve as an EMI shielding element for the electronic component without disposing or installing additional EMI shielding structures. Therefore, the electrical performance of the package structure can be improved without increasing the package size.

Furthermore, according to some arrangements of the present disclosure, the electrical contacts are taller than the protective element and the conductive wire under the bottom surface of the substrate. Therefore, in addition to electrically connecting to external components, the electrical contacts can further protect the protective element and the conductive wire from being damaged. Therefore, the reliability of the package structure can be improved without increasing the package size.

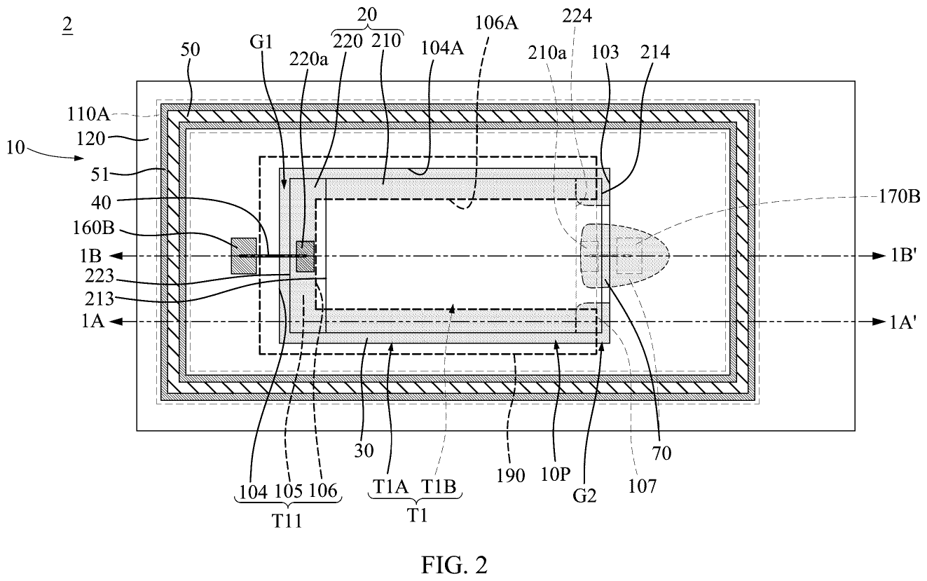

FIG. 2 is a top view of a package structure 2 in accordance with some arrangements of the present disclosure. The package structure 2 illustrated in FIG. 2 is similar to that in FIG. 1C, with differences therebetween as follows. In some arrangements, FIG. 1A shows a cross-section along a line 1A-1A′ in FIG. 2, and FIG. 1B shows a cross-section along a line 1B-1B′ in FIG. 2.

In some arrangements, the adhesive layer 30 is spaced apart from the protective element 70.

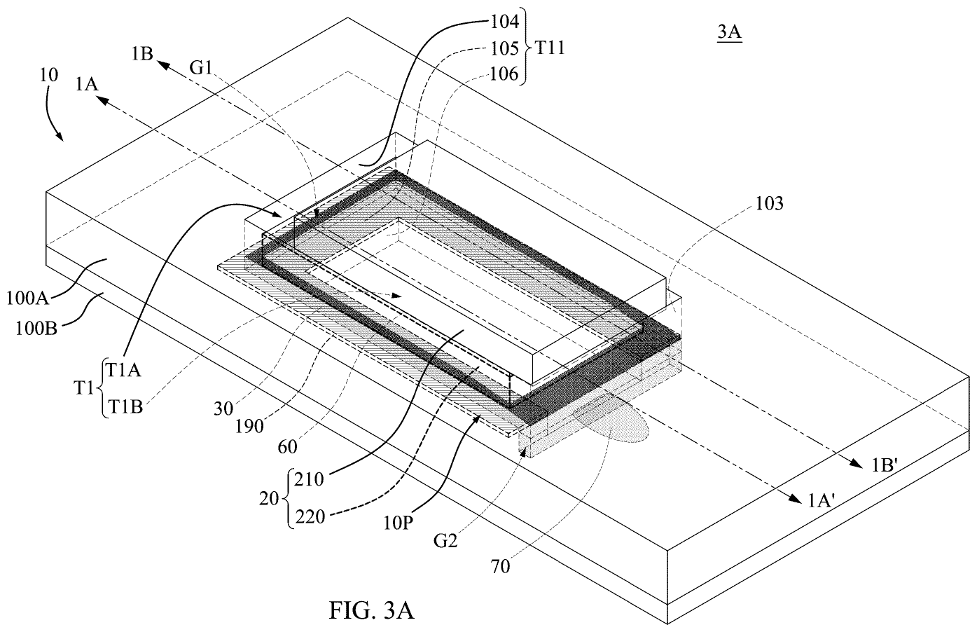

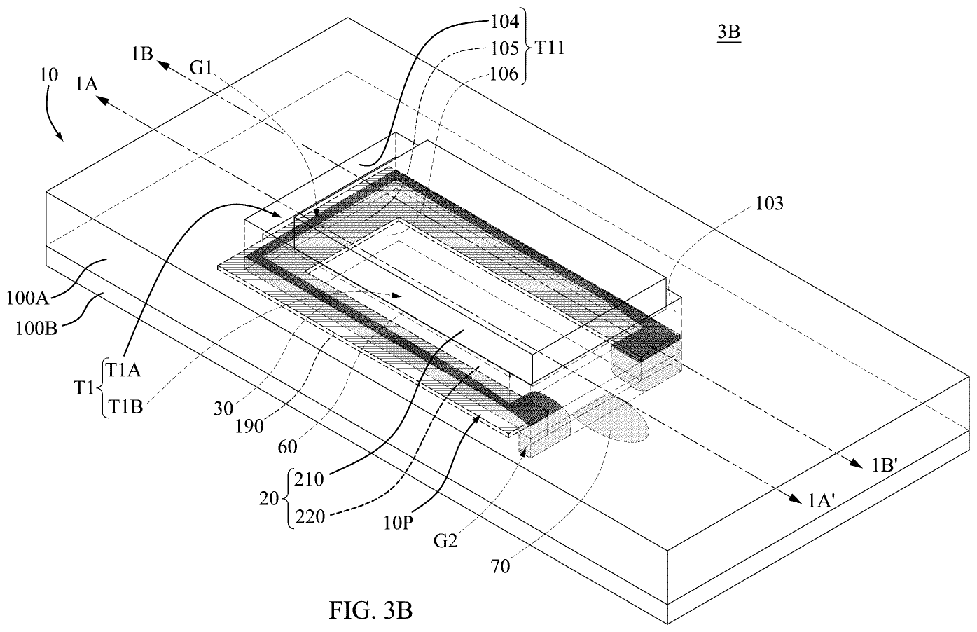

FIG. 3A is a perspective view of a package structure 3A in accordance with some arrangements of the present disclosure. In some arrangements, FIG. 1A shows a cross-section along a line 1A-1A′ in FIG. 3A, and FIG. 1B shows a cross-section along a line 1B-1B′ in FIG. 3A. In some arrangements, FIG. 3A shows a perspective view of the structure illustrated in FIG. 1C.

In some arrangements, the adhesive layer 30 connects to the protective element 70. In some arrangements, the adhesive layer 30 combined with the protective element 70 surrounds the electronic component 20.

FIG. 3B is a perspective view of a package structure 3B in accordance with some arrangements of the present disclosure. In some arrangements, FIG. 1A shows a cross-section along a line 1A-1A′ in FIG. 3B, and FIG. 1B shows a cross-section along a line 1B-1B′ in FIG. 3B. In some arrangements, FIG. 3B shows a perspective view of the structure illustrated in FIG. 2.

In some arrangements, the adhesive layer 30 is spaced apart from the protective element 70. In some arrangements, a portion of the straight vertical sidewall (e.g., the surface 103) of the through hole T1 is exposed by a gap between the adhesive layer 30 and the protective element 70.

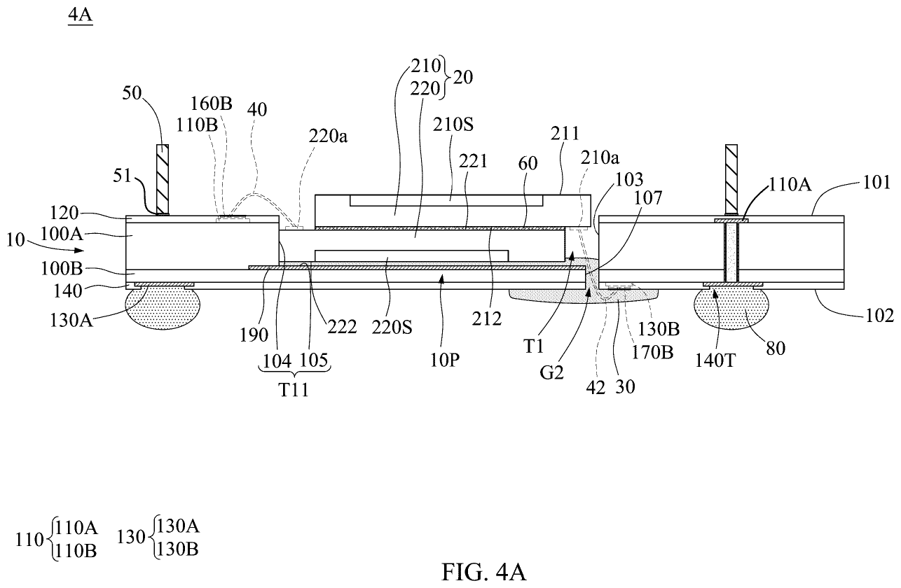

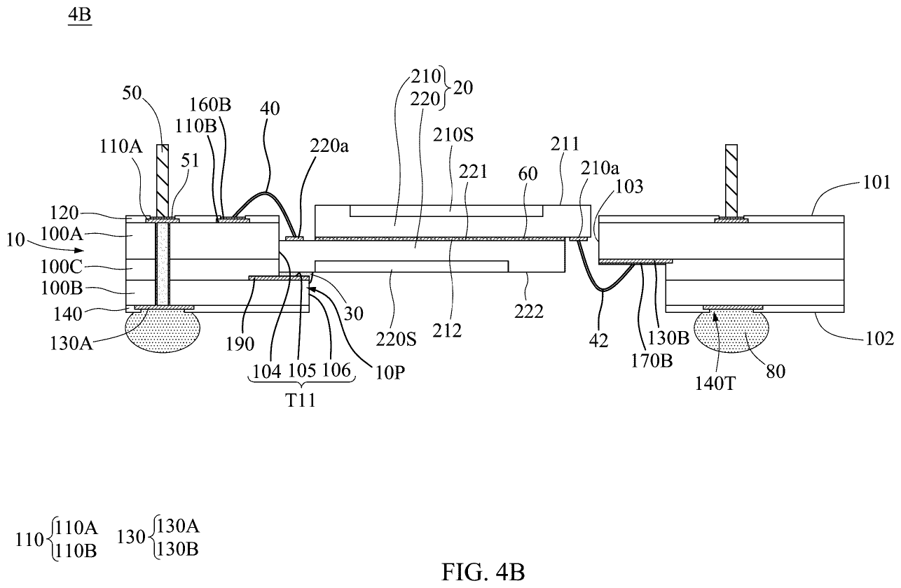

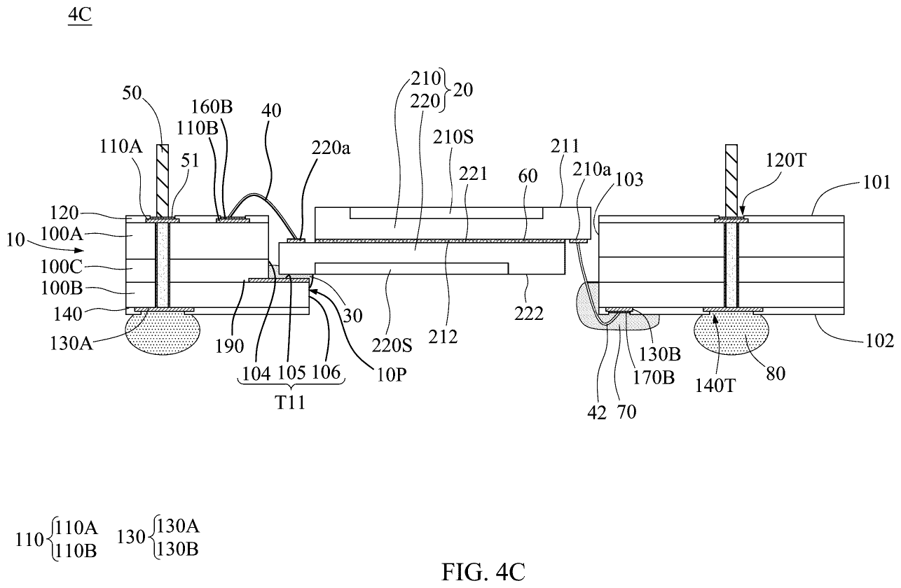

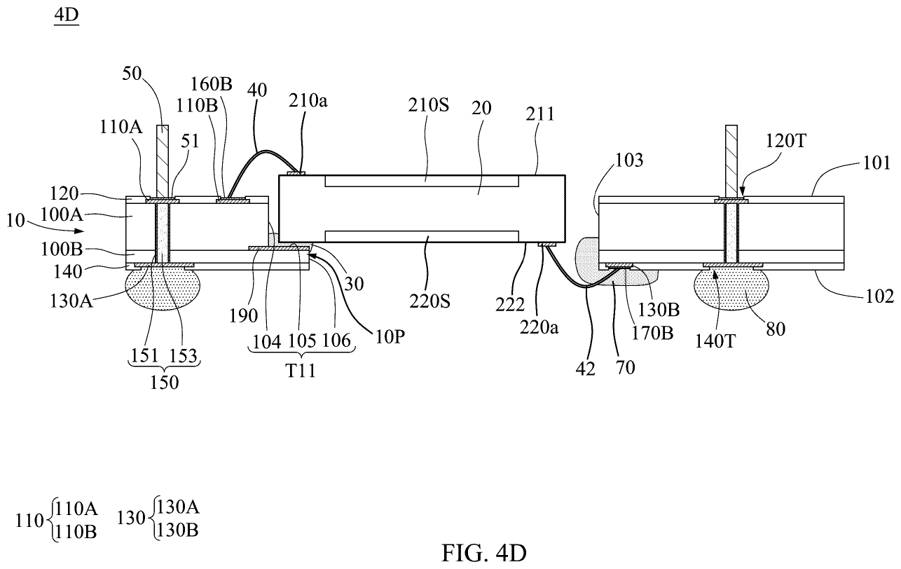

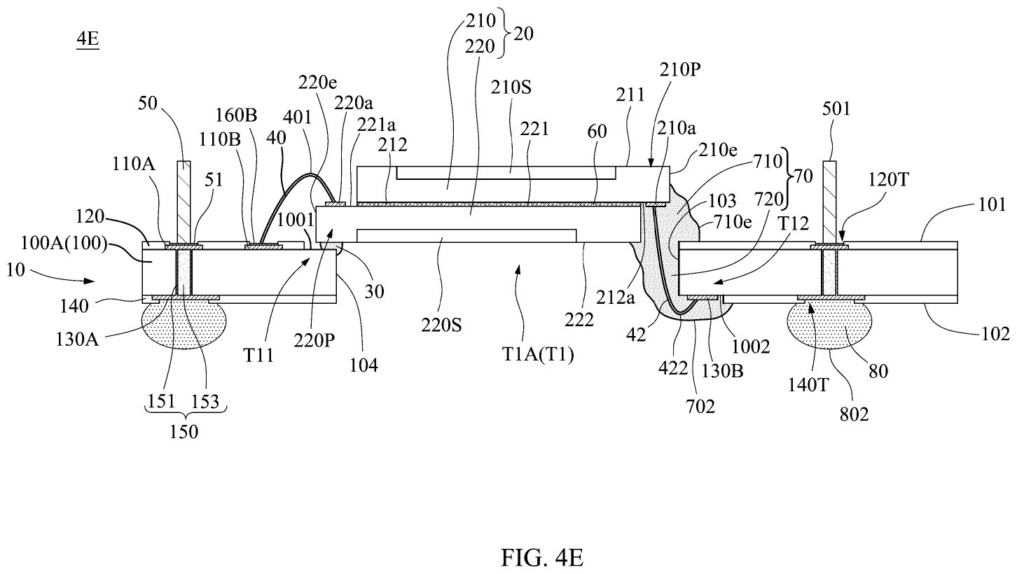

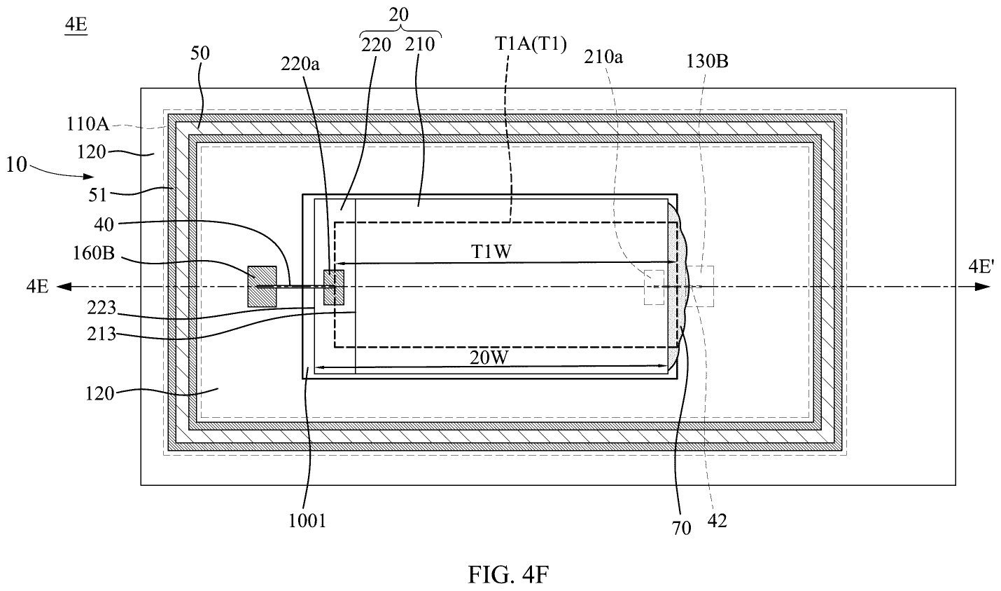

FIG. 4A is a cross-section of a package structure 4A in accordance with some arrangements of the present disclosure. The package structure 4A illustrated in FIG. 4A is similar to that in FIG. 1A, with differences therebetween as follows.

In some arrangements, the device 220 contacts the sidewall (e.g., the surface 104) of the through hole T1A. In some arrangements, there is no gap (e.g., the gap G1) between the device 220 and the sidewall (e.g., the surface 104) of the through hole T1A.

FIG. 4B is a cross-section of a package structure 4B in accordance with some arrangements of the present disclosure. The package structure 4B illustrated in FIG. 4B is similar to that in FIG. 1B, with differences therebetween as follows.

In some arrangements, the substrate 10 includes base layers 100A, 100B, and 100C. In some arrangements, the base layer 100C may be or include a core layer having a hardness greater than that of the base layers 100A and 100B. In some arrangements, the device 220 contacts the sidewall (e.g., the surface 104) of the through hole T1A. In some arrangements, there is no gap (e.g., the gap G1) between the device 220 and the sidewall (e.g., the surface 104) of the through hole T1A. In some arrangements, the base layers 100A, 100B, and 100C may independently include a dielectric material.

FIG. 4C is a cross-section of a package structure 4C in accordance with some arrangements of the present disclosure. The package structure 4C illustrated in FIG. 4C is similar to that in FIG. 1B, with differences therebetween as follows.

In some arrangements, the substrate 10 includes base layers 100A, 100B, and 100C. In some arrangements, the base layer 100C may be or include a core layer having a hardness greater than that of the base layers 100A and 100B.

FIG. 4D is a cross-section of a package structure 4D in accordance with some arrangements of the present disclosure. The package structure 4D illustrated in FIG. 4D is similar to that in FIG. 1B, with differences therebetween as follows.

In some arrangements, the electronic component 20 is a single device. In some arrangements, includes a sensing element 221S adjacent to the surface 211 and a sensing element 220S adjacent to the surface 222. In some arrangements, the sensing element 210S is exposed by the surface 211 of the electronic component 20, and the sensing element 220S is exposed by the surface 222 of the electronic component 20. In some arrangements, the sensing elements 210S and 220S are exposed by the through hole T1 of the substrate 10.

In some arrangements, the electronic component 20 includes at least pads 210a and 220a (also referred to as “conductive pads” or “conductive terminals”). In some arrangements, the pad 210a is on the surface 211 (or the top surface) of the electronic component 20, and the pad 220a is on the surface 222 (or the bottom surface) of the electronic component 20. In some arrangements, the pad 210a is protruded beyond the surface 211 of the electronic component 20, and the pad 220a is protruded beyond the surface 222 of the electronic component 20. In some arrangements, the pad 210a is electrically connected to the surface 101 of the substrate 10, and the pad 220a is electrically connected to the surface 102 of the substrate 10.

FIG. 4E is a cross-section of a package structure 4E in accordance with some arrangements of the present disclosure. FIG. 4F is a top view of a package structure 4E in accordance with some arrangements of the present disclosure. In some arrangements, FIG. 4E is a cross-section along a line 4E-4E′ in FIG. 4F. The package structure 4E illustrated in FIG. 4E and FIG. 4F is similar to that in FIGS. 1A-1C, with differences therebetween as follows.

In some arrangements, the substrate 10 has an upper surface 1001 and a lower surface 1002 opposite to the upper surface 1001. The upper surface 1001 may be a top surface of the base layer 100A exposed by the dielectric layer 120. The lower surface 1002 may be a bottom surface of the base layer 100A exposed by the dielectric layer 140. The dielectric layer 120 and the dielectric layer 140 may collective construct or be referred to as an insulating structure. In some arrangements, the insulating structure (or the dielectric layer 120) and the upper surface 1001 of the substrate 10 collectively define a stepped structure (e.g., a stepped sidewall structure T11) for disposing the electronic component 20. In some arrangements, the adhesive layer 30 is between the electronic component 20 and the stepped structure (or the stepped sidewall structure T11). In some arrangements, the insulating structure (or the dielectric layer 140) and the lower surface 1002 of the substrate 10 collectively define a stepped structure (e.g., a stepped sidewall structure T12) for disposing a pad (e.g., the portion 130B) which is electrically connected to the electronic component 20.

In some arrangements, the electronic component 20 has an upper surface (e.g., the surface 212) distal from the substrate 10 and a lower surface (e.g., the surface 221) closer to the substrate 10 than the upper surface is. In some arrangements, the pad 210a is on the upper surface (e.g., the surface 212). In some arrangements, the electronic component 20 includes an upper protrusion 210P and a lower protrusion 220P opposite to the upper protrusion 210P in a cross-sectional view perspective. In some arrangements, the pad 210a is disposed on a surface 212) of the upper protrusion 210P) facing the substrate 10. In some arrangements, the pad 220a is disposed on a surface 221a of the lower protrusion 220P facing away from the substrate 10. In some arrangements, an elevation of the pad 210a is higher than an elevation of the pad 220a with respect to the substrate 10. In some arrangements, the electronic component 20 is disposed at a side of the substrate 10. In some arrangements, the electronic component 20 has a side surface 220e and a side surface 210e opposite to the side surface 220e. In some arrangements, the side surface 220e vertically overlaps the substrate 10 (or the base layer 100A), and the side surface 210e vertically overlaps the through hole T1. In some arrangements, the side surface 210e does not vertically overlaps the substrate 10. Referring to FIG. 4F, in some arrangements, a width 20 W of the electronic component 20 is greater than a width T1W of the through hole T1.

In some arrangements, the conductive wire 40 connects the pad 220a to the upper surface 1001 of the substrate 10 without passing through the through hole T1. In some arrangements, the conductive wire 42 passes the through hole T1 (or the through hole T1A) to connect the pad 210a to the lower surface 1002 of the substrate 10. In some arrangements, a length of the conductive wire 42 is longer than a length of the conductive wire 40. In some arrangements, a curvature change of the conductive wire 42 is greater than a curvature change of the conductive wire 40. The term “curvature change” used herein may indicate a change in heights or elevations of the wire within a predetermined horizontal distance. The term “curvature change” may also reflect the slope of the wire.

In some arrangements, the protective element 70 encapsulates the conductive wire 42. In some arrangements, an elevation of a lower surface (e.g., the bottom surface 702) of the protective element 7) is lower than an elevation of the lower surface 100) of the substrate 10 with respect to the upper surface (e.g., the surface 212) of the electronic component 20. In some arrangements, the protective element 70 includes a portion 710 disposed outside the through hole T1 and a portion 720 within of the through hole T1. In some arrangements, a height or a thickness of the portion 710 is greater than a height or a thickness of the portion 720 in a direction (also referred to as “a first direction”) substantially perpendicular to the lower surface 1002. In some arrangements, an edge 710e of the portion 710 of the protective element 70 is protruded beyond an edge (e.g., the side surface 210e) of the electronic component 20 in a direction (also referred to as “a second direction”) substantially parallel to the lower surface 1002 (or in a second direction substantially perpendicular to the first direction). In some arrangements, the protective element 70 has a non-regular curvy surface.

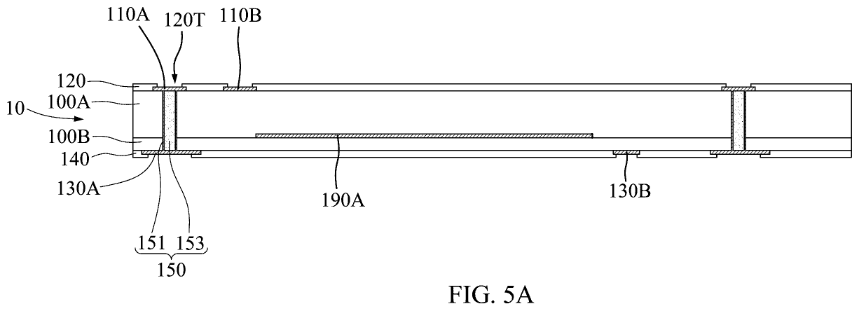

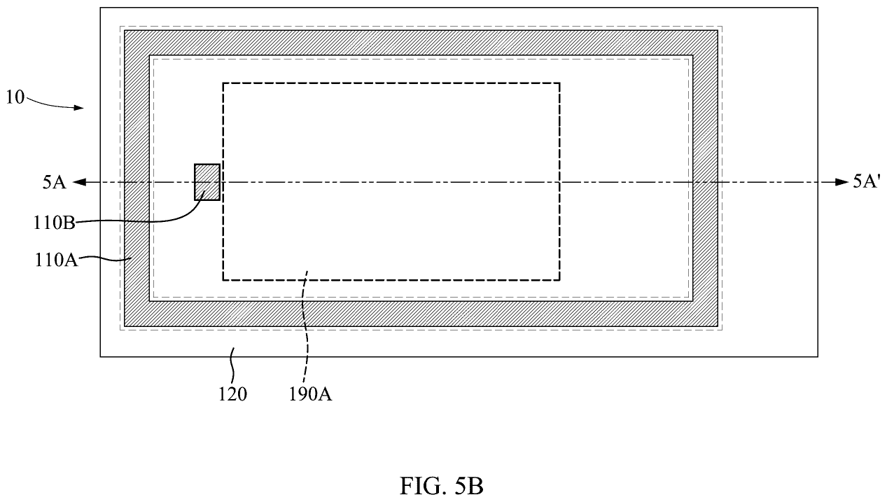

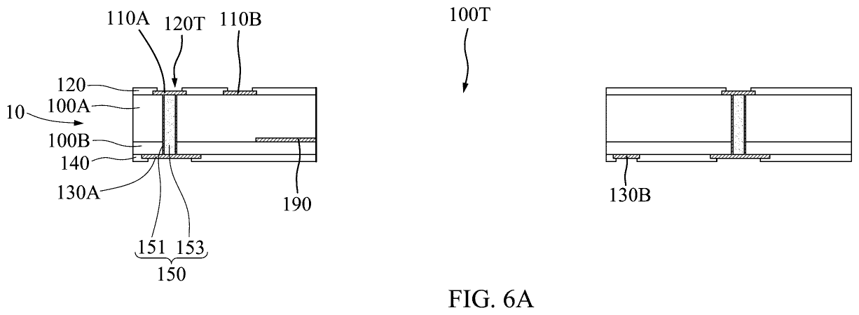

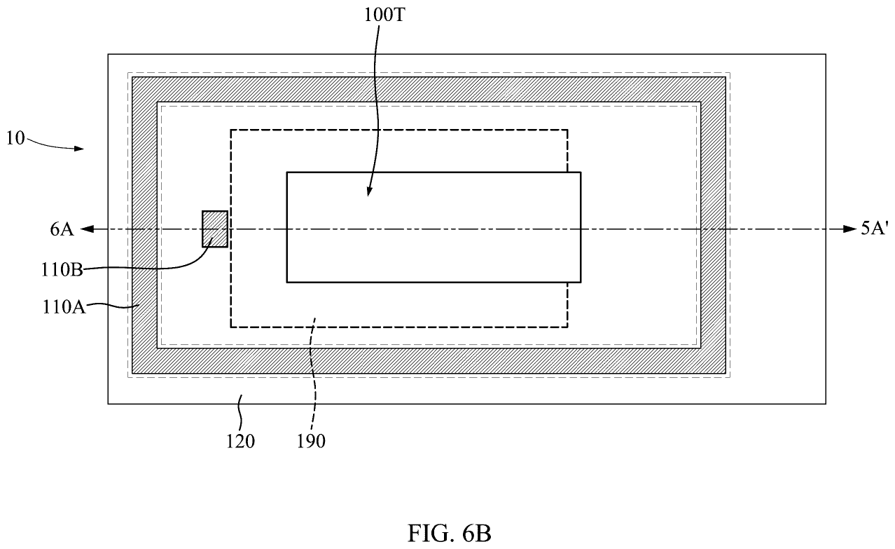

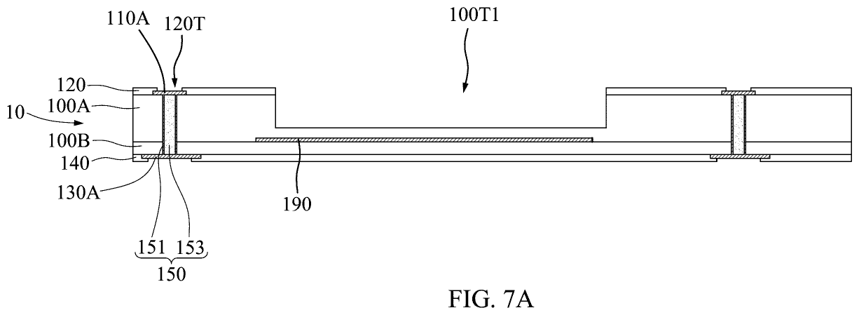

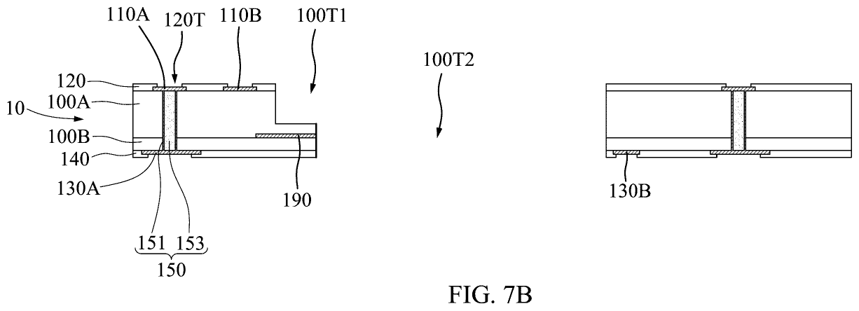

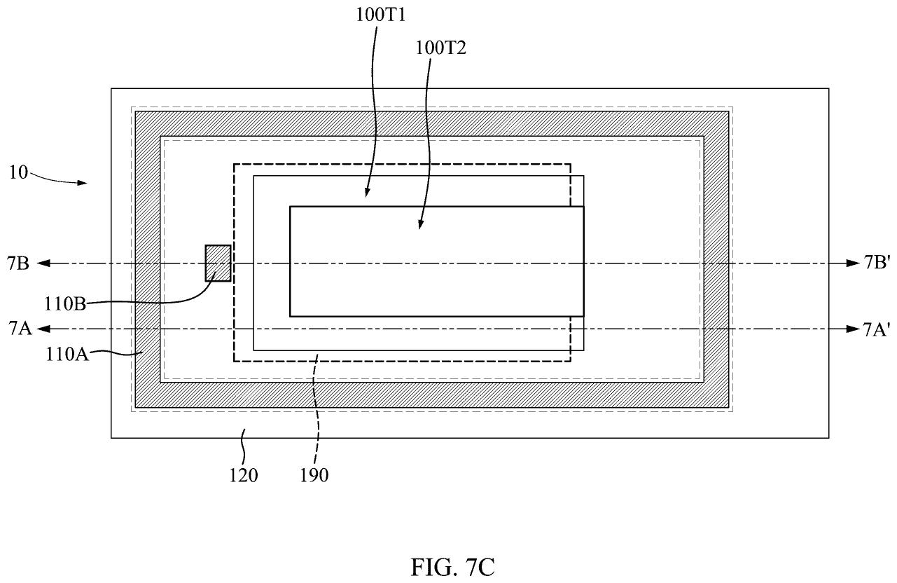

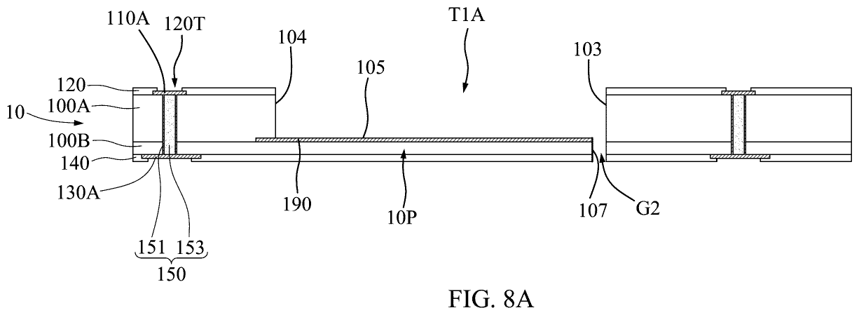

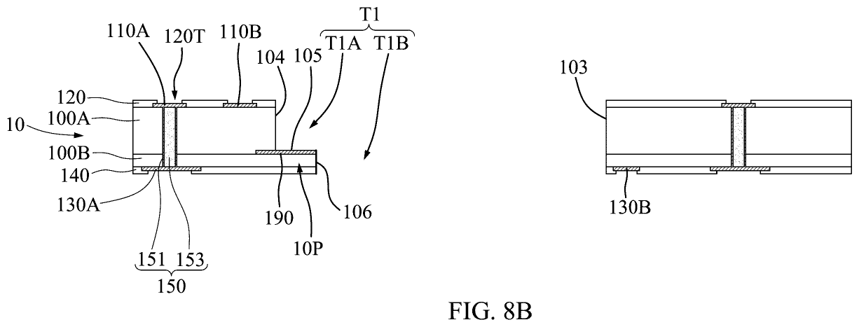

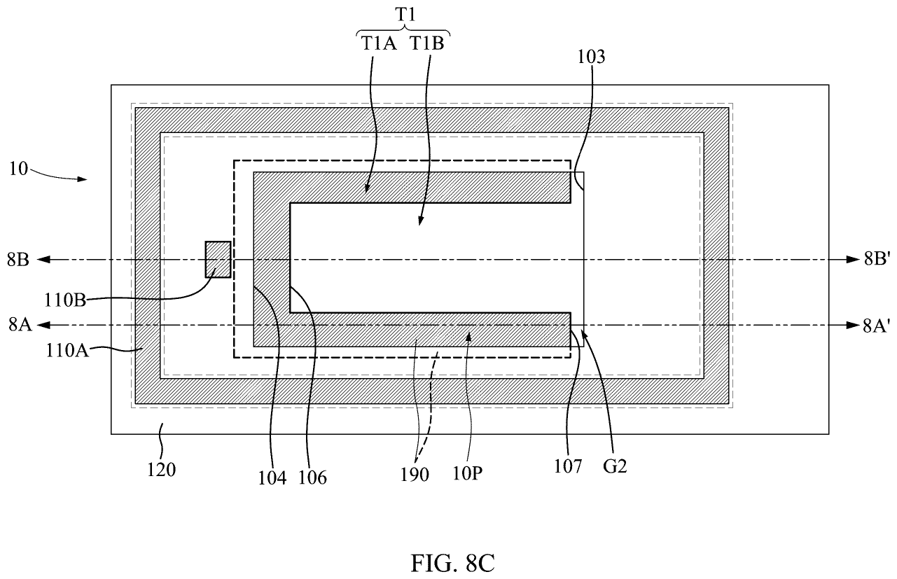

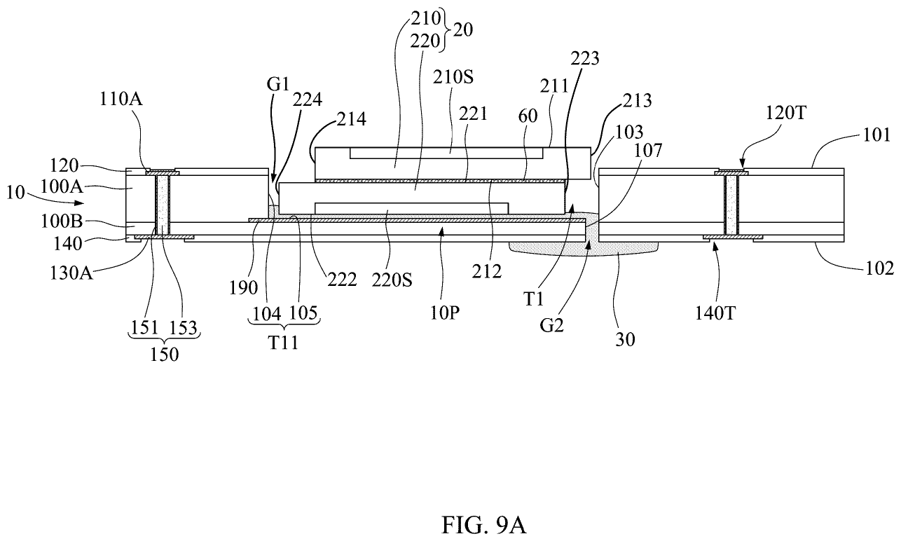

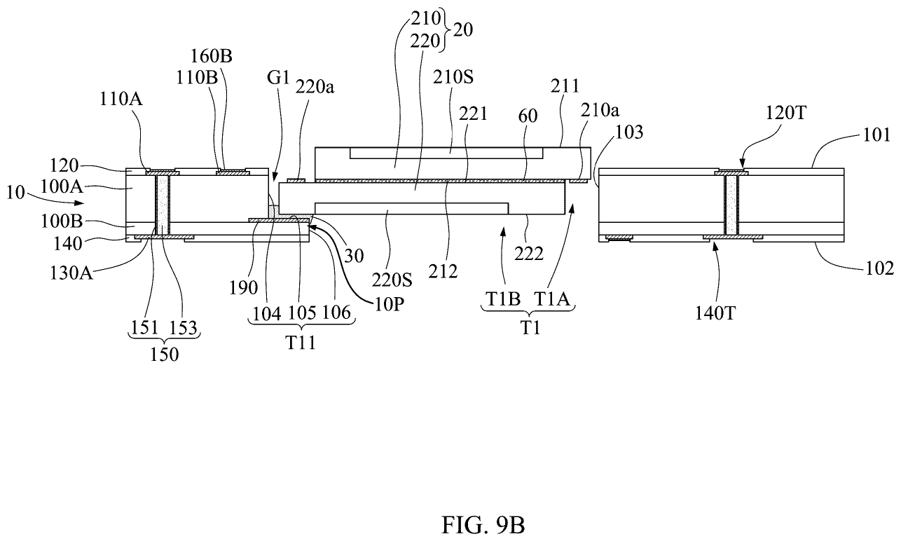

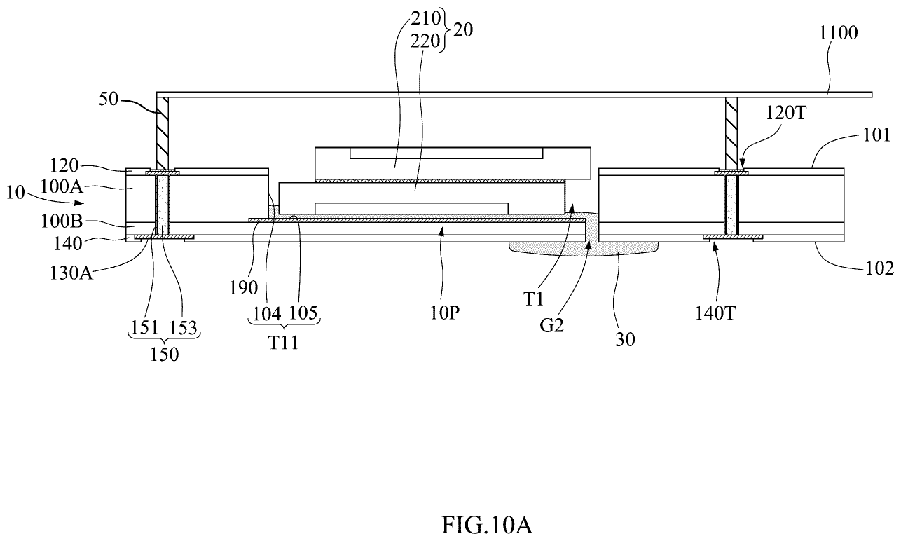

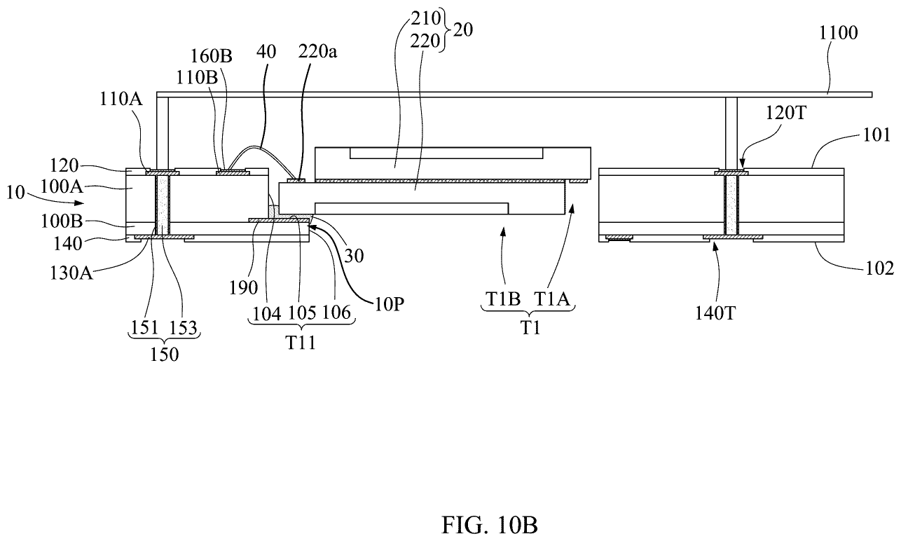

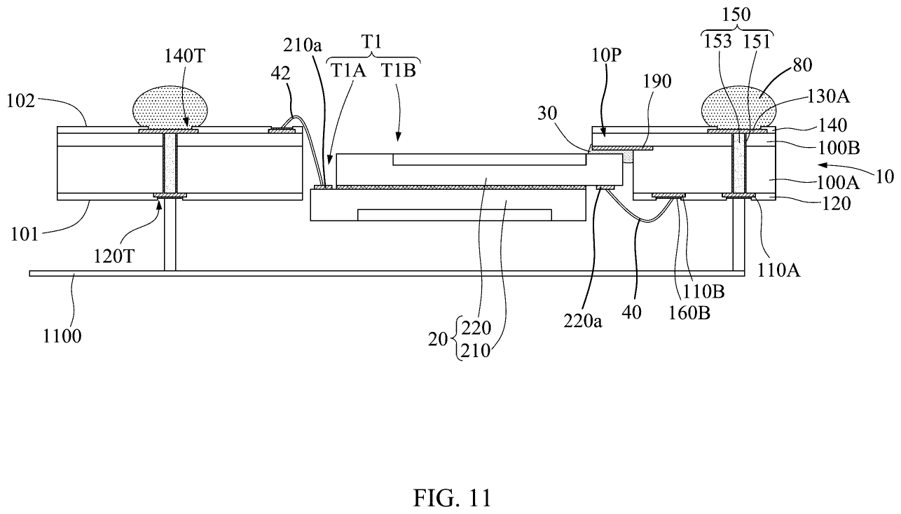

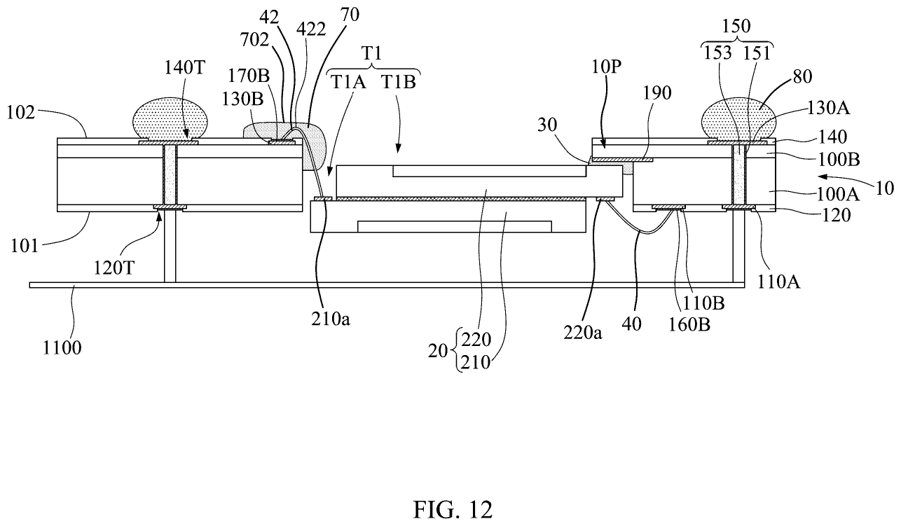

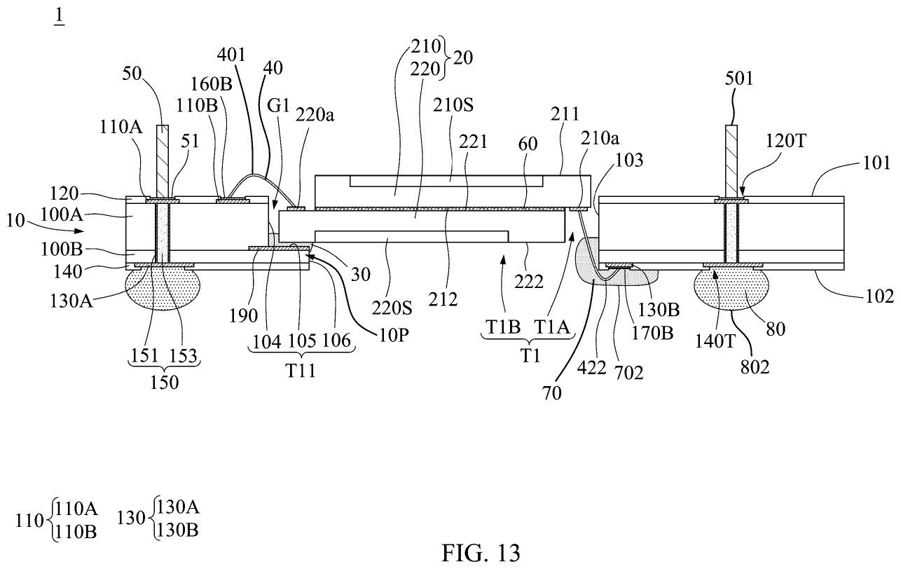

FIG. 5A, FIG. 5B, FIG. 6A, FIG. 6B, FIG. 7A, FIG. 7B, FIG. 7C, FIG. 8A, FIG. 8B, FIG. 8C, FIG. 9A, FIG. 9B, FIG. 10A, FIG. 10B, FIG. 11, FIG. 12, and FIG. 13 illustrate various stages of an exemplary method for manufacturing a package structure 1 in accordance with some embodiments of the present disclosure.

Referring to FIG. 5A and FIG. 5B, FIG. 5A is a cross-section along a line 5A-5A′ in FIG. 5B. A substrate 10 including base layers 100A and 100B, circuit layers 110 and 130, dielectric layers 120 and 140, one or more conductive vias 150, and a metal layer 190A may be provided. In some arrangements, the metal layer 190A is interposed between the base layer 100A and the base layer 100B.

Referring to FIG. 6A and FIG. 6B, FIG. 6A is a cross-section along a line 6A-6A′ in FIG. 6B. A through hole 100T may be formed penetrating the base layers 100A and 100B, the dielectric layers 120 and 140, and the metal layer 190A. In some arrangements, a portion of the metal layer 190A is removed to form a metal layer 190 having a U shape from a top view perspective. In some arrangements, the metal layer 190 is embedded in the base layers 100A and 100B. The through hole 100T may be formed by mechanical drilling.

Referring to FIG. 7A, FIG. 7B, and FIG. 7C, FIG. 7A is a cross-section along a line 7A-7A′ in FIG. 7C, and FIG. 7B is a cross-section along a line 7B-7B′ in FIG. 7C. A portion of the base layer 100A may be further removed to widen up a top portion of the through hole 100T to form an upper through hole 100T1 within the base layer 100A, and the lower portion of the through hole 100T forms a lower through hole 100T2 within the base layer 100B. The through hole 100T1 may be formed by mechanical drilling. The drilling may stop before exposing the metal layer 190.

Referring to FIG. 8A, FIG. 8B, and FIG. 8C, FIG. 8A is a cross-section along a line 8A-8A′ in FIG. 8C, and FIG. 8B is a cross-section along a line 8B-8B′ in FIG. 8C. An additional portion of the base layer 100A may be further removed to expose the metal layer 190 to form a through hole T1A within the base layer 100A, and the lower portion of the lower through hole 100T2 forms a through hole T1B within the base layer 100B. The additional portion of the base layer 100A may be removed by laser drilling. The metal layer 190 may serve as a laser stopper blocking the laser drilling from further removing portions of the base layer 100B under the metal layer 190. In some arrangements, a portion of the base layer 100B exposed by the metal layer 190 may be removed by laser drilling to form a gap G2 between a straight vertical sidewall (e.g., the surface 103) of the through hole T1B and an edge (e.g., the surface 107) of the base layer 100B. As such, a through hole T1 including the through holes T1A and T1B may be formed. A portion of the metal layer 190 may be exposed to the through hole T1. The portion of the metal layer 190 may define a platform 10P or a step surface (e.g., the surface 105) for supporting an electronic component.

According to some arrangements of the present disclosure, the through hole 100T1 is formed by mechanical drilling to remove a relatively large portion of the base layer 100A to preliminarily define the range of the through hole T1A, and then the remained portion of the base layer 100A is further removed by laser drilling to form the through hole T1A that ends precisely on the metal layer 190 (i.e., the laser stopper). The mechanical drilling may speed up the process for partially removing the base layer 100A, and the laser drilling followed by the mechanical drilling can precisely define the end or the bottom of the through hole T1A. Therefore, the overall time for forming the through hole T1A can be reduced, and the depth of the through hole T1A can be controlled precisely.

Referring to FIG. 9A and FIG. 9B, FIG. 9A illustrates a stage subsequent to that illustrated in FIG. 8A, and FIG. 9B illustrates a stage subsequent to that illustrated in FIG. 8B. An electronic component 20 including devices 210 and 220 and pads 210a and 220a may be disposed on the platform 10P in the through hole T1. In some arrangements, the electronic component 20 may be connected or adhered to the platform 10P by an adhesive layer 30.

Referring to FIG. 10A and FIG. 10B, FIG. 10A illustrates a stage subsequent to that illustrated in FIG. 9A, and FIG. 10B illustrates a stage subsequent to that illustrated in FIG. 9B. A conductive wire 40 may be provided or formed over the surface 101 of the substrate 10 to connect the circuit layer 110 to the pad 220a of the electronic component 20, and a spacer structure 50 may be adhered or attached to the substrate 10. In some arrangements, the spacer structure 50 is adhered to the portion 110A of the circuit layer 110 by an adhesive element 51 exposed by the opening 120T of the dielectric layer 120. In some arrangements, a temporary carrier 1100 is further disposed on the spacer structure 50.

Referring to FIG. 11, FIG. 11 illustrates a stage subsequent to that illustrated in FIG. 10B. The structure illustrated in FIGS. 10A and 10B may be flipped over, and the temporary carrier 1100 may serve as a temporary supporting carrier for the structure to undergo subsequent operations. Next, a conductive wire 42 may be provided or formed over the surface 102 of the substrate 10 to connect the circuit layer 130 to the pad 210a of the electronic component 20.

Referring to FIG. 12, a protective element 70 may be formed to encapsulate a portion of the conductive wire 42, and electrical contacts 80 may be disposed or formed on the surface 102 of the substrate 10. In some arrangements, the protective element 70 may be formed by a one drop filling (ODF) process. In some arrangements, the protective element 70 may be or include a sealing gel. In some arrangements, the protective element 70 may be or include a sealant.

Referring to FIG. 13, the structure illustrated in FIG. 12 may be flipped over, and the temporary carrier 1100 may be removed. As such, the package structure 1 illustrated in FIGS. 1A to 1C may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate having a through hole comprising a stepped sidewall structure including a tread;
an electronic component supported by the tread of the stepped sidewall structure; and
a stop layer disposed on a top surface of the tread.

2. The package structure as claimed in claim 1, wherein the stop layer comprises a first portion exposed to the through hole and a second portion not exposed to the through hole.

3. The package structure as claimed in claim 2, wherein an edge of the tread is substantially aligned with an edge of the stop layer.

4. The package structure as claimed in claim 1, wherein a sidewall defining the through hole has a first portion adjacent to the stop layer and a second portion distal from the stop layer, and a roughness of the first portion is less than a roughness of the second portion.

5. The package structure as claimed in claim 1, wherein the package structure further comprises a substantially vertical inner sidewall defining the through hole and having a substantially flat surface extending continuously from a top surface to a bottom surface of the substrate in a cross-sectional view perspective.

6. The package structure as claimed in claim 1, wherein the electronic component is partially disposed within the through hole and partially protruded beyond a surface of the substrate.

7. A package structure, comprising:
a substrate having a through hole extending between a top surface and a bottom surface of the substrate;
an electronic component disposed over the through hole of the substrate, wherein the electronic component has a lower surface adjacent to the top surface of the substrate and an upper surface distal from the top surface of the substrate, and the electronic component comprises a first pad adjacent to the upper surface of the electronic component; and
a first conductive element passing the through hole to connect the first pad to the bottom surface of the substrate.

8. The package structure as claimed in claim 7, further comprising a protective element encapsulating the first conductive element.

9. The package structure as claimed in claim 8, wherein the protective element comprises a first portion disposed outside of the through hole and a second portion within the through hole.

10. The package structure as claimed in claim 9, wherein a thickness of the first portion is greater than a thickness of the second portion in a first direction substantially perpendicular to the bottom surface of the substrate.

11. The package structure as claimed in claim 8, wherein the protective element has a non-uniform thickness along a direction substantially parallel to the top surface of the substrate.

12. The package structure as claimed in claim 10, wherein an edge of the first portion of the protective element is protruded beyond an edge of the electronic component in a second direction substantially perpendicular to the first direction.

13. The package structure as claimed in claim 8, wherein the protective element is protruded beyond the bottom surface of the substrate.

14. The package structure as claimed in claim 8, wherein the electronic component comprises an upper protrusion and a lower protrusion opposite to the upper protrusion in a cross-sectional view perspective.

15. The package structure as claimed in claim 14, wherein the first pad is disposed on a surface of the upper protrusion facing the substrate.

16. The package structure as claimed in claim 15, wherein the electronic component further comprises a second pad disposed on a surface of the lower protrusion facing away from the substrate.

17. The package structure as claimed in claim 16, further comprising a second conductive element connecting the second pad to the top surface of the substrate without passing through the through hole.

18. A package structure, wherein in a cross-sectional view perspective, the package structure comprises:
a substrate having a through hole; and
an electronic component disposed over the through hole, wherein the electronic component has a first side surface and a second side surface opposite to the first side surface, the first side surface vertically overlaps the substrate, and the second side surface does not vertically overlap the substrate.

19. The package structure as claimed in claim 18, further comprising an insulating structure, wherein the insulating structure and an upper surface of the substrate collectively define a first stepped structure for disposing the electronic component.

20. The package structure as claimed in claim 19, wherein the insulating structure and a lower surface of the substrate collectively define a second stepped structure for disposing a pad electrically connected to the electronic component.
